(19) United States
(12) Patent Application Publication
(10) Pub. No.: US 2025/0234611 A1
(43) Pub. Date: Jul. 17, 2025

(54) SOURCE/DRAIN STRUCTURES WITH VOID FOR SEMICONDUCTOR DEVICES

(71) Applicant: Taiwan Semiconductor Manufacturing Company, Ltd., Hsinchu (TW)

(72) Inventors: Tsz-Mei KWOK, Hsinchu (TW); Wei Hao LU, Taoyuan City (TW); Cheng-Yen WEN, Hsinchu City (TW); Ming-Hua YU, Hsinchu City (TW); Chii-Horng LI, Hsinchu County (TW)

(73) Assignee: Taiwan Semiconductor Manufacturing Company, Ltd., Hsinchu (TW)

(21) Appl. No.: 18/763,847

(22) Filed: Jul. 3, 2024

Related U.S. Application Data
(60) Provisional application No. 63/621,899, filed on Jan. 17, 2024.

(51) Int. Cl. H01L 29/08; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121

(57) ABSTRACT

The present disclosure describes a semiconductor device having a source/drain (S/D) structure with a void. The semiconductor device includes a stack of semiconductor layers on a substrate, a gate structure surrounding the stack of semiconductor layers, and a S/D structure on the substrate and in contact with the stack of semiconductor layers. The S/D structure includes a void below a top surface of the S/D structure.

### CROSS-REFERENCE TO RELATED APPLICATION

This application claims the benefit of U.S. Provisional Patent Application No. 63/621,899, titled “Source/Drain Epi with Void for Capacitance Reduction,” filed Jan. 17, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a source/drain structure with a void, in accordance with some embodiments.

FIGS. 2-4 illustrate partial cross-sectional views of a semiconductor device having a source/drain structure with a void, in accordance with some embodiments.

FIG. 5 is a flow diagram of a method for fabricating a semiconductor device having a source/drain structure with a void, in accordance with some embodiments.

FIGS. 6-17 illustrate partial cross-sectional views of a semiconductor device having a source/drain structure with a void at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor can have a gate structure wrapped around a channel structure to improve device performance. The nanostructure transistor can have inner spacers to isolate the gate structure from source/drain (S/D) structures. However, the parasitic capacitance of the S/D structures can limit the device performance of the nanostructure transistor.

Various embodiments in the present disclosure provide methods for forming a S/D structure with a void in a semiconductor device (e.g., a nanostructure transistor) and/or other semiconductor devices in an integrated circuit (IC). In some embodiments, a semiconductor device can include a stack of semiconductor layers on a substrate. A gate structure can wrap around the stack of semiconductor layers. A S/D structure can be formed on the substrate and in contact with the stack of semiconductor layers. The S/D structure can include a void below a top surface of the S/D structure. In some embodiments, a first ratio of a horizontal dimension of the void to a width of the S/D structure can range from about 0.1 to about 0.8, and a second ratio of a vertical dimension of the void to a height of the S/D structure can range from about 0.05 to about 0.8. With the void in the S/D structure, the parasitic capacitance of the S/D structure can be reduced and the device performance of the semiconductor device can be increased.

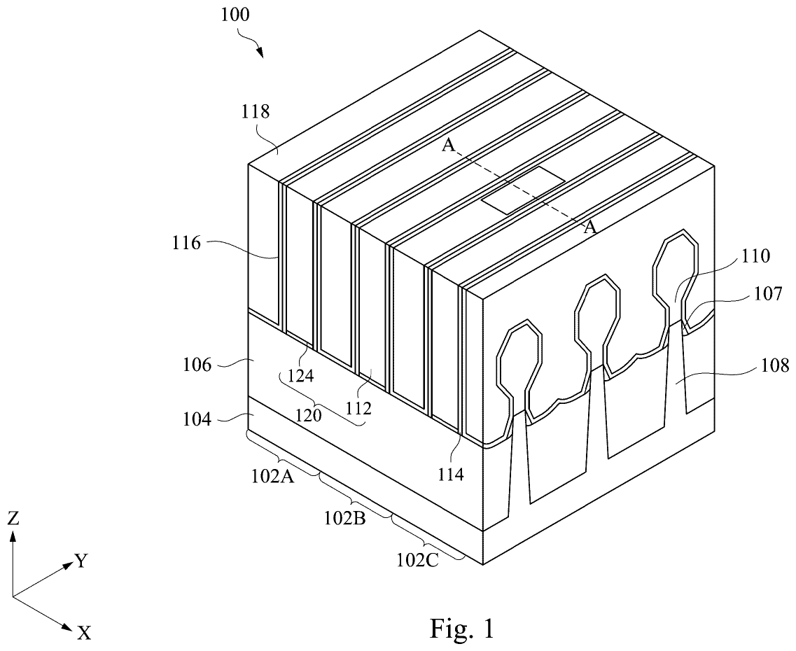

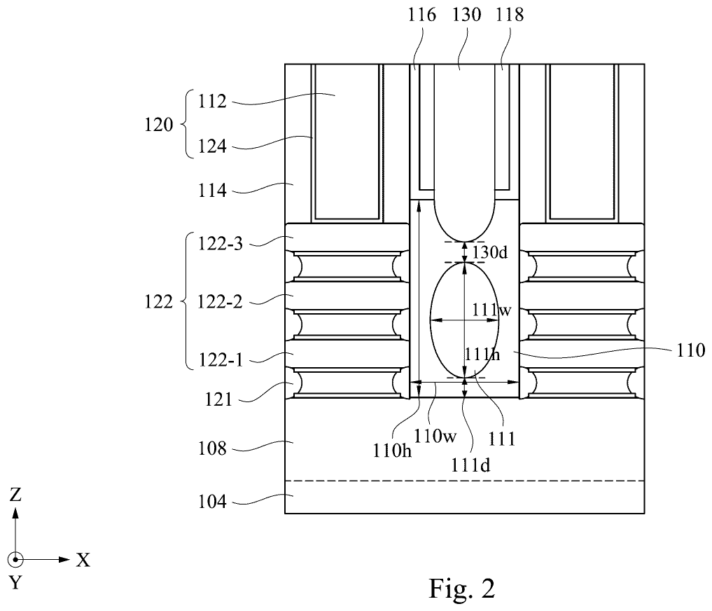

FIG. 1 illustrates an isometric view of a semiconductor device 100 having a S/D structure with a void, in accordance with some embodiments. FIGS. 2-4 illustrate partial cross-sectional views of semiconductor device 100 across line A-A shown in FIG. 1, in accordance with some embodiments. In some embodiments, FIGS. 2-4 illustrate various embodiments of the epitaxial structure with one or more voids. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-4, semiconductor device 100 having transistors 102A-102C can be formed on a substrate 104 and can be isolated by shallow trench isolation (STI) regions 106. Each of transistors 102A-102C can include fin structures 108, sidewall spacers 107, gate structures 120, gate spacers 114, inner spacers 121, S/D structures 110, etch stop layer (ESL) 116, interlayer dielectric (ILD) layer 118, and S/D contact structures 130. In some embodiments, as shown in FIGS. 2-4, transistors 102A-102C can have nanostructures 122-1, 122-2, and 122-3 (collectively referred to as “nanostructures 122”) on fin structures 108.

Referring to FIGS. 1-4, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-4, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-4, nanostructures 122 and fin structures 108 can extend along an X-axis for transistors 102A-102C. In some embodiments, nanostructures 122 and fin structures 108 can be disposed on substrate 104. Nanostructures 122 can include a set of nanostructures 122-1, 122-2, and 122-3, which can be in the form of semiconductor layers, nanosheets, nanowires, or nano-ribbons. Each of nanostructures 122 can act as a channel structure and form a channel region underlying gate structures 120 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIG. 2-4, nanostructures 122 under gate structures 120 can form channel regions of semiconductor device 100 and represent current carrying channel structures of semiconductor device 100. Though three layers of nanostructures 122 are shown in FIGS. 2-4, transistors 102A-102C can have any number of nanostructures 122.

Referring to FIGS. 1-4, gate structures 120 can include gate dielectric layer 124 and gate electrode 112. In some embodiments, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1-4, gate electrode 112 can be disposed on gate dielectric layer 124. In some embodiments, gate electrode 112 can include one or more work function metal layers and a metal fill. The one or more work function metal layers can include work function metals to tune the threshold voltage (Vₜ) of transistors 102A-102C. In some embodiments, gate electrode 112 for NFET and PFET devices can have the same work-function metal. In some embodiments, gate electrode 112 for NFET and PFET devices can have different work-function metals. In some embodiments, as shown in FIG. 2-4, each of nanostructures 122 can be wrapped around by gate structures 120, for which gate structures 120 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-4, gate spacers 114 can be disposed on sidewalls of gate structures 120, sidewall spacers 107 can be disposed on sidewalls of fin structures 108, and inner spacers 121 can be disposed between gate structures 120 and S/D structures 110. Gate spacers 114, sidewall spacers 107, and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114, sidewall spacers 107, and inner spacers 121 can include a same insulating material. In some embodiments, gate spacers 114, sidewall spacers 107, and inner spacers 121 can include different insulating materials. Gate spacers 114, sidewall spacers 107, and inner spacers 121 can include a single layer or a stack of insulating layers. Gate spacers 114, sidewall spacers 107, and inner spacers 121 can have a low-k material with a dielectric constant less than about 3.9 (e.g., about 3.5, about 3.0, or about 2.8).

S/D structures 110 can be disposed on fin structures 108 and in contact with nanostructures 122. In some embodiments, S/D structures 110 can be disposed between adjacent stacks of nanostructures 122 and on opposing sides of gate structures 120. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium and imparts a strain on the channel regions under gate structures 120. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structures 110 can have a width 110w along an X-axis ranging from about 20 nm to about 40 nm. In some embodiments, S/D structures 110 can have a height 110h along a Z-axis ranging from about 50 nm to about 100 nm.

In some embodiments, as shown in FIGS. 2-4, S/D structures 110 can include one or more voids 111-1 and 111-2 (collectively referred to as “voids 111”) below a top surface of S/D structures 110. In some embodiments, voids 111 can have any geometric shape, such as an oval, a circle, a polygon, a cone, and an irregular shape. In some embodiments, as shown in FIG. 2, S/D structures 110 can include one void 111 enclosed by S/D structures 110. In some embodiments, void 111 may not be in contact with nanostructures 122, fin structures 108, or inner spacers 121. In some embodiments, void 111 can have a horizontal dimension 111w along an X-axis (e.g., width) ranging from about 2 nm to about 20 nm. In some embodiments, void 111 can have a vertical dimension 111h along a Z-axis (e.g., height) ranging from about 2 nm to about 50 nm. In some embodiments, a first ratio of the horizontal dimension 111w to width 110w of S/D structures 110 can range from about 0.1 to about 0.8. In some embodiments, a second ratio of the vertical dimension 111h to height 110h of S/D structures 110 can range from about 0.05 to about 0.8. If horizontal dimension 111w is less than about 2 nm, vertical dimension 111h is less than about 2 nm, the first ratio is less than about 0.1, or the second ratio is less than about 0.05, the parasitic capacitance of S/D structures 110 may not be reduced and the device performance of semiconductor device 100 may not be improved. If horizontal dimension 111w is greater than about 20 nm, vertical dimension 111h is greater than about 50 nm, the first ratio is greater than about 0.8, or the second ratio is greater than about 0.8, the resistance of S/D structures 110 may increase and the device performance of semiconductor device 100 may be degraded. In some embodiments, as shown in FIG. 2, a distance 111d between voids 111 and top surfaces of fin structures 108 can range from about 5 nm to about 20 nm.

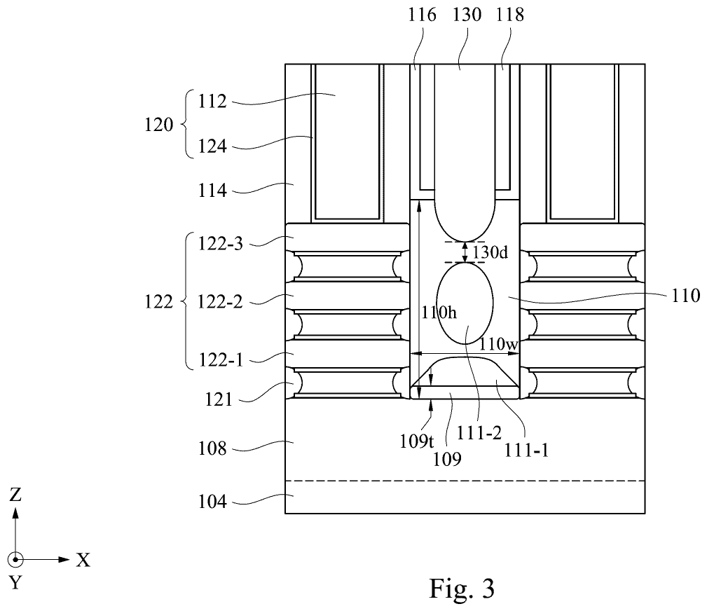

In some embodiments, as shown in FIG. 3, a dielectric layer 109 can be disposed on fin structures 108 and substrate 104, and S/D structures 110 can be disposed on dielectric layer 109. In some embodiments, dielectric layer 109 can include silicon oxide, silicon nitride, silicon oxynitride, silicon carbonitride, silicon oxycarbide, silicon oxycarbonitride, or other suitable dielectric materials. In some embodiments, dielectric layer 109 can have a thickness 109t ranging from about 1 nm to about 15 nm. In some embodiments, a top surface of dielectric layer 109 can be below a bottom surface of bottom nanostructures 122-1 to avoid blocking the contact between nanostructures 122 and S/D structures 110. In some embodiments, dielectric layer 109 can reduce leakage current of semiconductor device 100. If thickness 109t is less than about 1 nm, dielectric layer 109 may not reduce leakage current of semiconductor device 100. In some embodiments, if thickness 109t is greater than about 15 nm, dielectric layer 109 may block the contact between nanostructures 122 and S/D structures 110 and thus reduce drive current and degrade the device performance of semiconductor device 100.

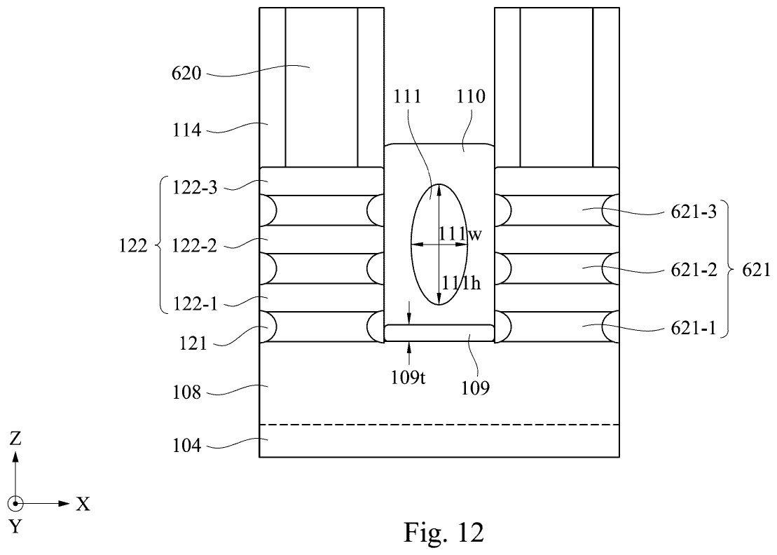

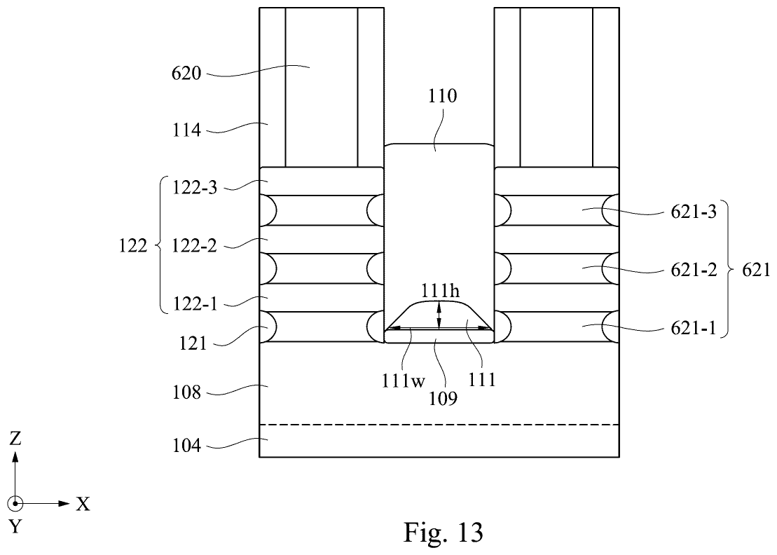

In some embodiments, with dielectric layer 109, S/D structures can include a first void 111-1 enclosed by S/D structures 110 and dielectric layer 109 and a second void 111-2 enclosed by S/D structures 110. In some embodiments, first void 111-1 and second void 111-2 can be separated (e.g., as shown in FIG. 3). In some embodiments, first void 111-1 and second void 111-2 can be merged into single voids 111 at different locations (e.g., as shown in FIGS. 12 and 13). In some embodiments, each of voids 111-1 and 111-2 can have a horizontal dimension along an X-axis (e.g., width) ranging from about 2 nm to about 20 nm and a vertical dimension along a Z-axis (e.g., height) ranging from about 2 nm to about 50 nm. In some embodiments, a first ratio of the horizontal dimension to width 110w of S/D structures 110 can range from about 0.1 to about 0.8, and a second ratio of the vertical dimension to height 110h of S/D structures 110 can range from about 0.05 to about 0.8. These ranges of the dimensions of first and second voids 111-1 and 111-2 can reduce the parasitic capacitance of S/D structures 110 and improve device performance of semiconductor device 100. In some embodiments, as shown in FIG. 3, the horizontal dimension of void 111-1 can be less than the horizontal dimension of void 111-2. The vertical dimension of void 111-1 can be greater than the horizontal dimension of void 111-2. In some embodiments, as shown in FIG. 3, void 111-1 can be below void 111-2 and a top surface of void 111-2 can be lower than a bottom surface of top nanostructure 122-3.

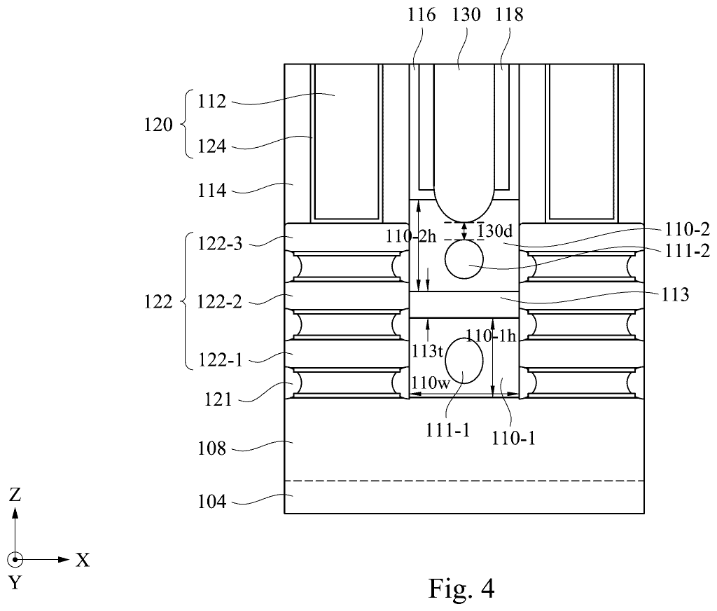

In some embodiments, as shown in FIG. 4, a first S/D structure 110-1 can be disposed on fin structures 108, a dielectric layer 113 can be disposed on first S/D structure 110-1, and a second S/D structure 110-2 can be disposed on dielectric layer 113. In some embodiments, first and second S/D structures 110-1 and 110-2 can include different types of dopants. For example, first S/D structure 110-1 can include a p-type dopant and can be a p-type S/D structure. Second S/D structure 110-2 can include an n-type dopant and can be an n-type S/D structure. In some embodiments, first S/D structure 110-1 can be in contact with bottom nanostructures 122-1 to form S/D regions of a first type nanostructure transistor, e.g., a p-type nanostructure transistor. In some embodiments, second S/D structure 110-2 can be in contact with top nanostructures 122-3 to form S/D regions of a second type nanostructure transistor different from the first type, e.g., an n-type nanostructure transistor.

In some embodiments, dielectric layer 113 can be disposed between first and second S/D structures 110-1 and 110-2. In some embodiments, dielectric layer 113 can include silicon oxide, silicon nitride, silicon oxynitride, silicon carbonitride, silicon oxycarbide, silicon oxycarbonitride, or other suitable dielectric materials. In some embodiments, dielectric layer 113 can isolate second S/D structure 110-2 from first S/D structure 110-1. In some embodiments, dielectric layer 113 can have a thickness 113t ranging from about 1 nm to about 15 nm. In some embodiments, if thickness 113t is less than about 1 nm, dielectric layer 113 may not isolate second S/D structure 110-2 from first S/D structure 110-1. In some embodiments, if thickness 113t is greater than about 15 nm, the dimensions of first and second S/D structures 110-1 and 110-2 may be reduced and thus the resistance of S/D structures 110-1 and 110-2 may increase and the device performance of semiconductor device 100 may be reduced.

In some embodiments, as shown in FIG. 4, first S/D structure 110-1 can include a first void 111-1 enclosed by first S/D structure 110-1. Second S/D structure 110-2 can include a second void 111-2 enclosed by second S/D structure 110-2. In some embodiments, first and second S/D structures 110-1 and 110-2 can have a width 110w along an X-axis ranging from about 20 nm to about 40 nm. In some embodiments, first S/D structure 110-1 can have a first height 110-1h along a Z-axis ranging from about 20 nm to about 50 nm. Second S/D structure 110-2 can have a second height 110-2h along a Z-axis ranging from about 20 nm to about 50 nm. In some embodiments, each of voids 111-1 and 111-2 can have a horizontal dimension along an X-axis (e.g., width) ranging from about 2 nm to about 20 nm and a vertical dimension along a Z-axis (e.g., height) ranging from about 2 nm to about 50 nm. In some embodiments, a first ratio of the horizontal dimension to width 110w of S/D structures 110-1 and 110-2 can range from about 0.1 to about 0.8, and a second ratio of the vertical dimension to first height 110-1h or second height 110-2h can range from about 0.05 to about 0.8. These ranges of the dimensions of first and second voids 111-1 and 111-2 can reduce the parasitic capacitance of first and second S/D structures 110-1 and 110-2 and improve device performance of semiconductor device 100. Though FIGS. 2-4 illustrate one or two voids 111 in S/D structures 110, S/D structures 110 can have any number of voids 111.

Referring to FIGS. 1-4, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1-4, semiconductor device 100 can further include S/D contact structures 130. In some embodiments, S/D contact structures 130 can be disposed on S/D structures 110. In some embodiments, S/D contact structures 130 can include a silicide layer and a metal contact (not shown). In some embodiments, the silicide layer can include metal silicide and can provide a lower resistance interface between the metal contact and S/D structures 110. Examples of metal used for forming the metal silicide include cobalt, titanium, and nickel. In some embodiments, the metal contact can include conductive materials, such as tungsten, aluminum, and cobalt. In some embodiments, as shown in FIGS. 1-4, S/D contact structures 130 can extend through ILD layer 118 and into S/D structures 110. In some embodiments, S/D contact structures 130 can extend below a top surface of S/D structures 110 for a distance ranging from about 5 nm to about 20 nm. In some embodiments, a distance 130d along a Z-axis between S/D contact structures 130 and voids 111 can range from about 4 nm to about 20 nm. If distance 130d is less than about 4 nm, the contact resistance between S/D contact structures 130 and S/D structures 110 may increase. If distance 130d is greater than about 20 nm, S/D contact structures 130 may not extend into S/D structures 110 and the contact resistance between S/D contact structures 130 and S/D structures 110 may also increase. In some embodiments, as shown in FIG. 4, second void 111-2 can have a smaller size than first void 111-1 to satisfy distance 130d.

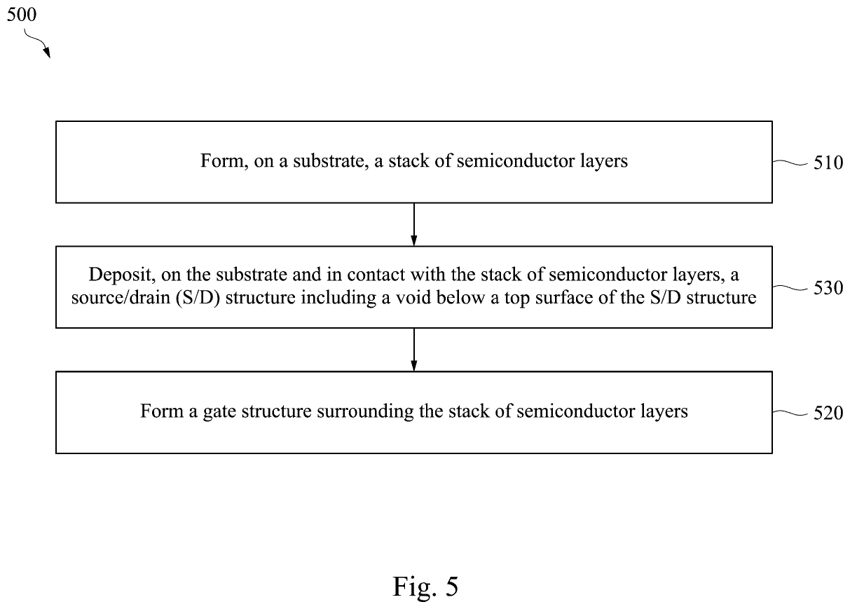

FIG. 5 is a flow diagram of a method 500 for fabricating semiconductor device 100 having a S/D structure with a void, in accordance with some embodiments. Method 500 may not be limited to nanostructure transistor devices and can be applicable to other devices that would benefit from the S/D structure with a void. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

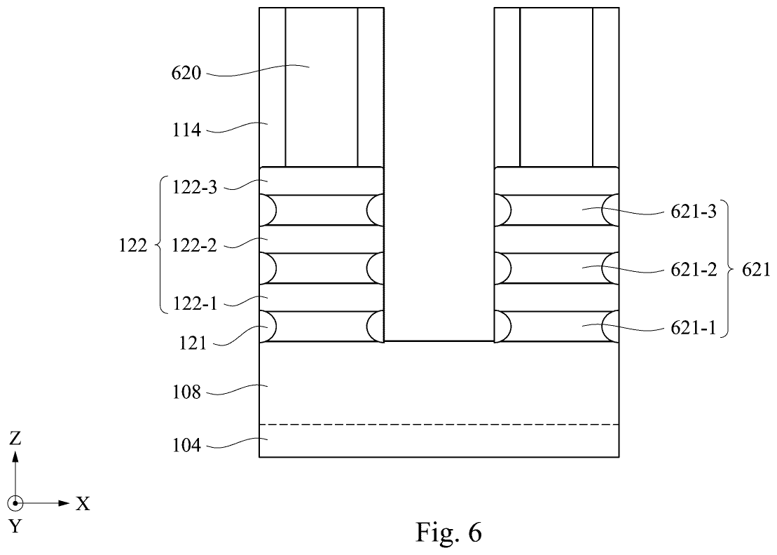

For illustrative purposes, the operations illustrated in FIG. 5 will be described with reference to the example fabrication process for fabricating semiconductor device 100 as illustrated in FIGS. 6-17. FIGS. 6-17 illustrate partial cross-sectional views of semiconductor device 100 having a S/D structure with a void at various stages of its fabrication, in accordance with some embodiments. In some embodiments, FIGS. 6-17 illustrate partial cross-sectional views of semiconductor device 100 along line A-A as shown in FIG. 1 at various stages of its fabrication. Elements in FIGS. 6-17 with the same annotations as elements in FIGS. 1-4 are described above.

In referring to FIG. 5, method 500 begins with operation 510 and the process of forming a stack of semiconductor layers on a substrate. For example, as shown in FIG. 6, nanostructures 122 and nanostructures 621-1, 621-2, and 621-3 (collectively referred to as “nanostructures 621”) stacked on fin structures 108 can be formed on substrate 104. In some embodiments, nanostructures 122 and 621 can be stacked in an alternate configuration. In some embodiments, nanostructures 122 and 621 can be epitaxially grown on substrate 104 and subsequently patterned to form nanostructures 122 and 621. In some embodiments, nanostructures 122 and 621 can be in the form of semiconductor layers, nanosheets, nanowires, or nano-ribbons. In some embodiments, nanostructures 122 and 621 can include semiconductor materials similar to or different from substrate 104. In some embodiments, fin structures 108 can include the same semiconductor material as substrate 104. In some embodiments, nanostructures 122 and 621 can include different semiconductor materials. For example, nanostructures 122 can include silicon and nanostructures 621 can include silicon germanium.

Embodiments of fin structures 108 and nanostructures 122 and 621 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures.

The formation of nanostructures 122 and 621 can be followed by the formation of STI regions 106 between adjacent stacks of nanostructures 122 and 621, the formation of sacrificial gate structures 620 on nanostructures 122 and STI regions 106, the formation of gate spacers 114 on sidewalls of sacrificial gate structures 620, the vertical recess of nanostructures 122 and 621, and the formation of inner spacers 121, as shown in FIG. 6. In some embodiments, sacrificial gate structures 620 can include polysilicon. In some embodiments, gate spacers 114 and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, the vertical recess of nanostructures 122 and 621 can expose fin structures 108 to ensure complete removal of bottom nanostructures 621-1 on fin structures 108. In some embodiments, inner spacers 121 can be formed adjacent to end portions of nanostructures 122. In some embodiments, the formation of inner spacers 121 can include the lateral recess of nanostructures 621 and the deposition and trim of a spacer layer. These processes are not described in detail for clarity.

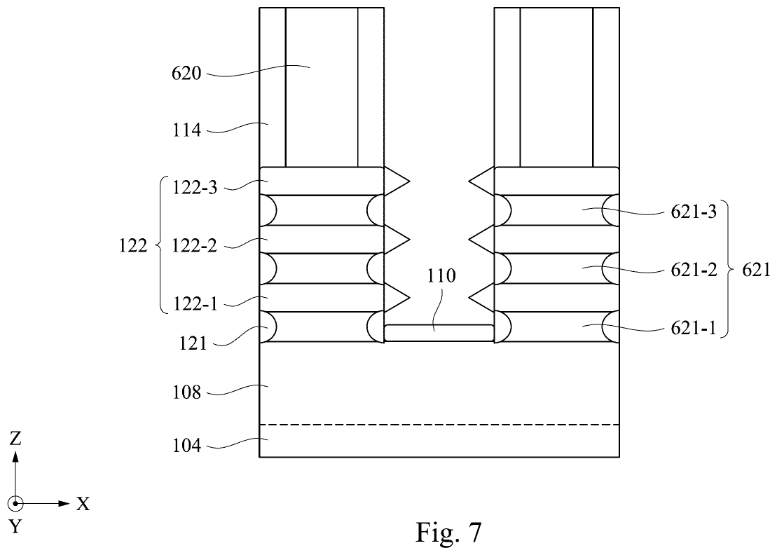

Referring to FIG. 5, in operation 520, a S/D structure is deposited on the substrate and in contact with the stack of semiconductor layers. The S/D structure can include a void below a top surface of the S/D structure. For example, as shown in FIGS. 7-9, S/D structures 110 can be epitaxially grown on fin structures 108 and substrate 104. S/D structures 110 can include a void 111 below a top surface of S/D structures 110. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 120.

In some embodiments, S/D structures 110 can be epitaxially grown by (i) chemical vapor deposition (CVD), such as low pressure CVD (LPCVD), atomic layer CVD (ALCVD), ultrahigh vacuum CVD (UHVCVD), reduced pressure CVD (RPCVD), and other suitable CVD; (ii) molecular beam epitaxy (MBE) processes; (iii) any suitable epitaxial process; or (iv) a combination thereof. In some embodiments, S/D structures 110 can be grown by an epitaxial deposition/partial etch process, which can repeat the epitaxial deposition/partial etch process multiple times. Such repeated deposition/partial etch process can be referred to as a cyclic deposition-etch (CDE) process. The CDE process can reduce epitaxial defects formed during the growth and can control the profiles of S/D structures 110. In some embodiments, S/D structures 110 can be in-situ doped with n-type or p-type dopants during the epitaxial growth process.

In some embodiments, S/D structures 110 can include silicon and can be in-situ doped during the epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during the epitaxial growth process using p-type dopants, such as boron, indium, and gallium. In some embodiments, S/D structures 110 can include one or more epitaxial layers, where each epitaxial layer can have different compositions and/or different dopant concentrations.

In some embodiments, during the epitaxial growth process of S/D structures 110, a cleaning gas, such as hydrogen chloride, can remove the epitaxial structures grown on dielectric layers, such as gate spacers 114 and inner spacers 121. In some embodiments, a flow rate of the cleaning gas can range from about 50 sccm to about 200 sccm. If the flow rate is less than about 50 sccm, the epitaxial structures may grow on both semiconductor materials (e.g., fin structures 108 and nanostructures 122) and dielectric layers (e.g., gate spacers 114 and inner spacers 121). If the flow rate is greater than about 200 sccm, the epitaxial structures may grow on semiconductor materials (e.g., fin structures 108) but not dielectric layers (e.g., gate spacers 114 and inner spacers 121). In some embodiments, the flow rate of the cleaning gas can be controlled to adjust a position of void 111, for example, at the center or edge of S/D structures 110.

In some embodiments, a deposition pressure and/or a deposition temperature of S/D structures 110 can be controlled to adjust a growth rate of S/D structures 110 and thus a dimension of void 111. In some embodiments, the deposition pressure can range from about 100 torr to about 300 torr. In some embodiments, the deposition temperature can range from about 550° C. to about 750° C. If the deposition pressure is less than about 100 torr or the deposition temperature is less than about 550° C., the growth rate of S/D structures 110 may be too slow such that void 111 may not be formed in S/D structures 110. If the deposition pressure is greater than about 300 torr or the deposition temperature is greater than about 750° C., the growth rate of S/D structures 110 may be too fast such that void 111 may be too large and the resistance of S/D structures 110 may increase.

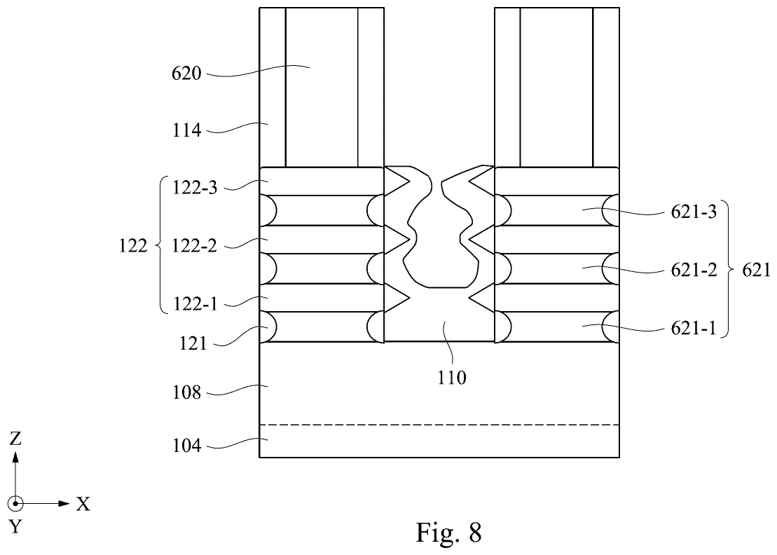

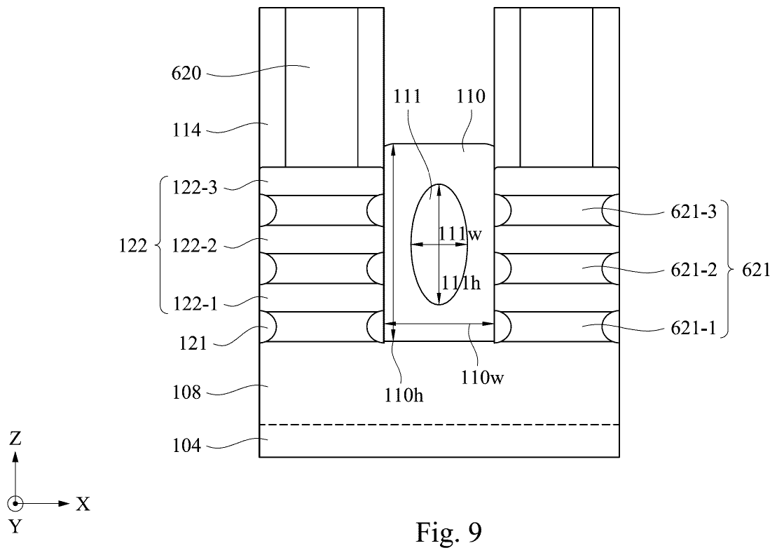

In some embodiments, as shown in FIG. 7, S/D structures 110 can be epitaxially grown first on top surfaces of fin structures 108 and end portions of nanostructures 122. In some embodiments, as shown in FIG. 8, S/D structures 110 can continue to be epitaxially grown on fin structures 108 and end portions of nanostructures 122. In some embodiments, S/D structures 110 on top nanostructures 122-3 can have a higher growth rate than S/D structures 110 on bottom nanostructures 122-1 and inner spacers 121. In some embodiments, as shown in FIG. 9, S/D structures 110 grown on top nanostructures 122-3 can merge and void 111 can be formed inside S/D structures 110 below the top surface of S/D structures 110.

In some embodiments, void 111 may not be in contact with nanostructures 122, fin structures 108, or inner spacers 121. In some embodiments, void 111 can have horizontal dimension 111w along an X-axis (e.g., width) ranging from about 2 nm to about 20 nm. In some embodiments, void 111 can have vertical dimension 111h along a Z-axis (e.g., height) ranging from about 2 nm to about 50 nm. In some embodiments, a first ratio of horizontal dimension 111w to width 110w of S/D structures 110 can range from about 0.1 to about 0.8. In some embodiments, a second ratio of vertical dimension 111h to height 110h of S/D structures 110 can range from about 0.05 to about 0.8. If horizontal dimension 111w is less than about 2 nm, vertical dimension 111h is less than about 2 nm, the first ratio is less than about 0.1, or the second ratio is less than about 0.05, the parasitic capacitance of S/D structures 110 may not be reduced and the device performance of semiconductor device 100 may not be improved. If horizontal dimension 111w is greater than about 20 nm, vertical dimension 111h is greater than about 50 nm, the first ratio is greater than about 0.8, or the second ratio is greater than about 0.8, the resistance of S/D structures 110 may increase and the device performance of semiconductor device 100 may be degraded.

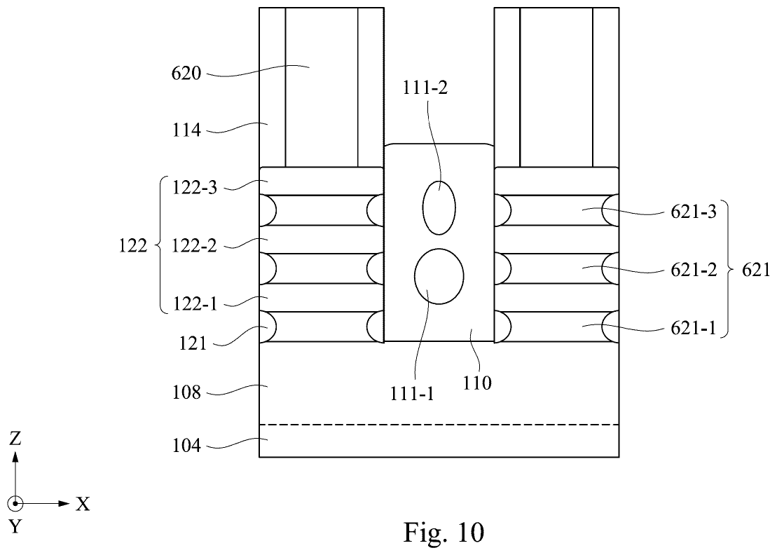

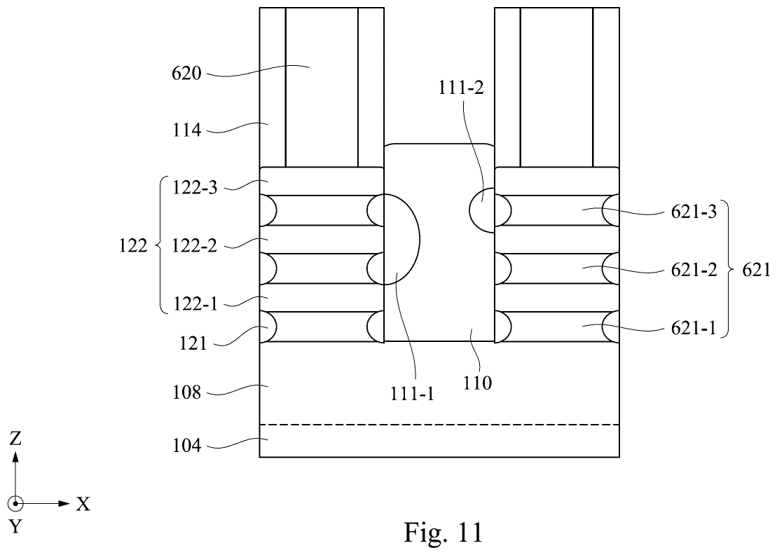

In some embodiments, S/D structures can include two voids 111-1 and 111-2 disposed vertically along a Z-axis as shown in FIG. 10, or disposed horizontally along an X-axis as shown in FIG. 11. In some embodiments, the flow rate of the cleaning gas, the deposition pressure, and the deposition temperature during the growth of S/D structures 110 can be adjusted to form voids 111-1 and 111-2 in FIGS. 10 and 11. In some embodiments, the growth conditions can be adjusted such that S/D structures 110 in FIGS. 10 and 11 can have a slower growth rate than S/D structures 110 in FIG. 9. As a result, voids 111-1 and 111-2 can be formed in S/D structures 110 instead of one void 111. In some embodiments, S/D structures grown on inner spacers 121 can be removed with the cleaning gas during the growth of S/D structures 110. As a result, voids 111-1 and 111-2 can be formed adjacent to inner spacers 121, as shown in FIG. 11. In some embodiments, as shown in FIG. 10, voids 111-1 and 111-2 can be enclosed by S/D structures 110. In some embodiments, as shown in FIG. 10, voids 111-1 and/or 111-2 can be in contact with and partially enclosed by inner spacers 121 and/or nanostructures 122. In some embodiments, each of voids 111-1 and 111-2 in FIGS. 10 and 11 can have a horizontal dimension along an X-axis (e.g., width) ranging from about 2 nm to about 20 nm. In some embodiments, each of voids 111-1 and 111-2 in FIGS. 10 and 11 can have a vertical dimension along a Z-axis (e.g., height) ranging from about 2 nm to about 50 nm. In some embodiments, a first ratio of the horizontal dimension to width 110w of S/D structures 110 can range from about 0.1 to about 0.8. In some embodiments, a second ratio of the vertical dimension to height 110h of S/D structures 110 can range from about 0.05 to about 0.8.

In some embodiments, as shown in FIGS. 12 and 13, dielectric layer 109 can be formed on fin structures 108 prior to the growth of S/D structures 110. S/D structures 110 can be epitaxially grown on dielectric layer 109 and between adjacent stacks of nanostructures 122. In some embodiments, dielectric layer 109 can be formed on fin structures 108 using a directional deposition method. In some embodiments, dielectric layer 109 can have thickness 109t ranging from about 1 nm to about 15 nm. In some embodiments, a top surface of dielectric layer 109 can be below a bottom surface of bottom nanostructures 122-1 to avoid blocking the contact between nanostructures 122 and S/D structures 110. In some embodiments, dielectric layer 109 can reduce leakage current of semiconductor device 100.

In some embodiments, by adjusting the flow rate of the cleaning gas, the deposition pressure, and the deposition temperature during the growth of S/D structures 110, void 111 can be formed in S/D structures 110 as shown in FIG. 12 or can be formed in contact with dielectric layer 109 as shown in FIG. 13. In some embodiments, as shown in FIG. 12, void 111 can be enclosed by S/D structures 110. In some embodiments, as shown in FIG. 13, void 111 can be in contact with and enclosed by dielectric layer 109 and S/D structures 110. In some embodiments, void 111 in FIGS. 12 and 13 can have horizontal dimension 111w along an X-axis (e.g., width) ranging from about 2 nm to about 20 nm. In some embodiments, void 111 in FIGS. 12 and 13 can have vertical dimension 111h along a Z-axis (e.g., height) ranging from about 2 nm to about 50 nm. In some embodiments, a first ratio of horizontal dimension 111w to width 110w of S/D structures 110 can range from about 0.1 to about 0.8. In some embodiments, a second ratio of vertical dimension 111h to height 110h of S/D structures 110 can range from about 0.05 to about 0.8.

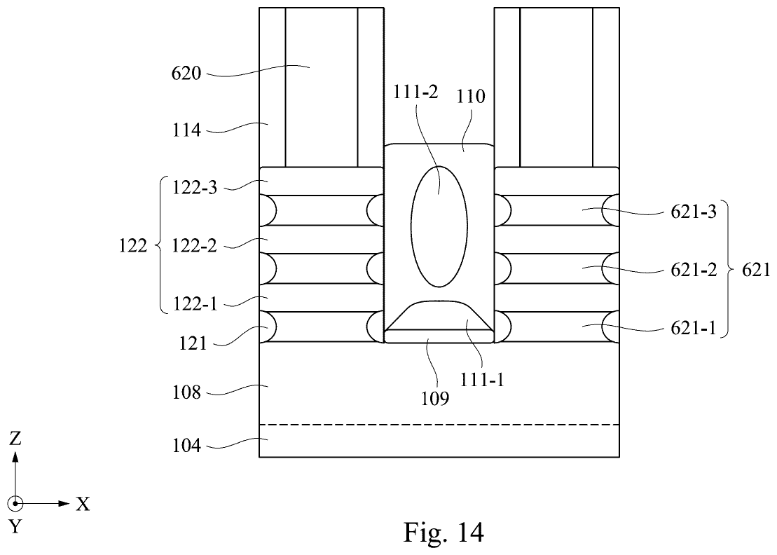

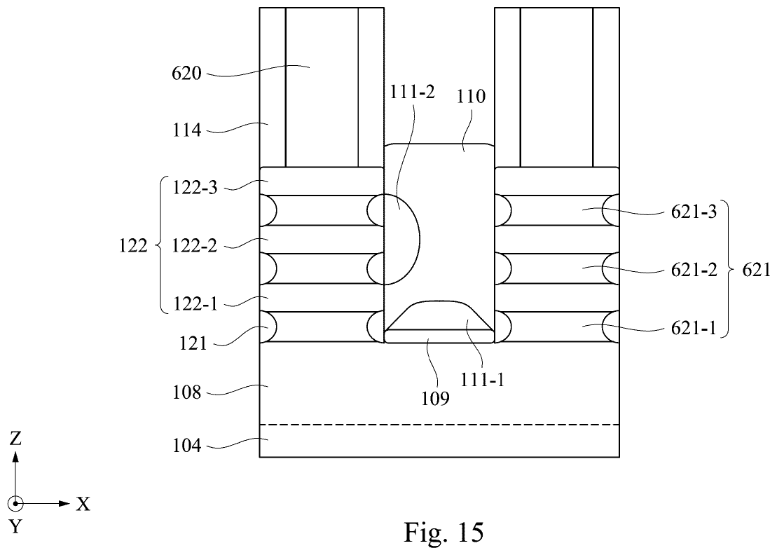

In some embodiments, S/D structures can be formed on dielectric layer 109 and include two voids 111-1 and 111-2 disposed vertically along a Z-axis as shown in FIG. 14, or disposed horizontally along an X-axis as shown in FIG. 15. In some embodiments, the flow rate of the cleaning gas, the deposition pressure, and the deposition temperature during the growth of S/D structures 110 can be adjusted to form voids 111-1 and 111-2 in FIGS. 14 and 15. In some embodiments, as shown in FIG. 14, voids 111-1 and 111-2 can be enclosed by S/D structures 110 and dielectric layer 109. In some embodiments, as shown in FIG. 15, voids 111-1 and/or 111-2 can be in contact with and partially enclosed by inner spacers 121 and/or nanostructures 122. In some embodiments, each of voids 111-1 and 111-2 in FIGS. 14 and 15 can have a horizontal dimension along an X-axis (e.g., width) ranging from about 2 nm to about 20 nm. In some embodiments, each of voids 111-1 and 111-2 in FIGS. 14 and 15 can have a vertical dimension along a Z-axis (e.g., height) ranging from about 2 nm to about 50 nm. In some embodiments, a first ratio of the horizontal dimension to width 110w of S/D structures 110 can range from about 0.1 to about 0.8. In some embodiments, a second ratio of the vertical dimension to height 110h of S/D structures 110 can range from about 0.05 to about 0.8.

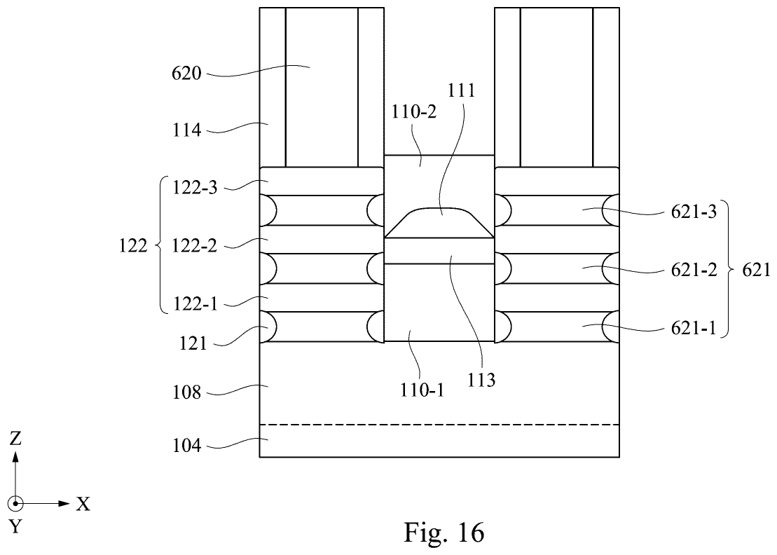

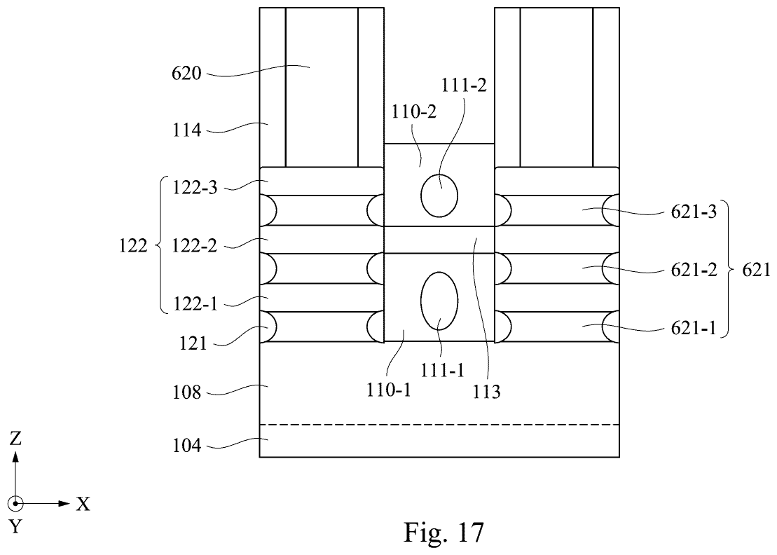

In some embodiments, as shown in FIGS. 16 and 17, a first S/D structures 110-1 can be formed on fin structures 108, a dielectric layer 113 can be formed on first S/D structures 110-1, and a second S/D structures 110-2 can be formed on dielectric layer 113. In some embodiments, first S/D structures 110-1 can be in contact with bottom nanostructures 122-1, dielectric layer 113 can be in contact with middle nanostructures 122-2, and second S/D structures 110-2 can be in contact with top nanostructures 122-3. In some embodiments, first S/D structures 110-1 can include a first type dopant. For example, first S/D structures 110-1 can include a p-type dopant and can act as a p-type S/D region of a bottom nanostructure transistor formed with bottom nanostructure 122-1. In some embodiments, second S/D structures 110-2 can include a second type dopant complimentary to the first type dopant. For example, second S/D structures 110-2 can include an n-type dopant and can act as an n-type S/D region of a top nanostructure transistor formed with top nanostructure 122-3. In some embodiments, semiconductor device 100 in FIGS. 16 and 17 can be referred to as complementary FET (CFET) devices.

In some embodiments, as shown in FIG. 16, void 111 can be formed in second S/D structures 110-2 and enclosed by second S/D structures 110-2 and dielectric layer 113. In some embodiments, as shown in FIG. 17, void 111-1 can be formed in first S/D structures 110-1 and void 111-2 can be formed in second S/D structures 110-2. Void 111-1 can be enclosed by first S/D structures 110-1 and void 111-2 can be enclosed by second S/D structures 110-2. In some embodiments, the flow rate of the cleaning gas, the deposition pressure, and the deposition temperature during the growth of S/D structures 110-1 and 110-2 can be adjusted to form voids 111, 111-1, and 111-2 in FIGS. 16 and 17. In some embodiments, each of voids 111, 111-1, and 111-2 in FIGS. 16 and 17 can have a horizontal dimension along an X-axis (e.g., width) ranging from about 2 nm to about 20 nm. In some embodiments, each of voids 111, 111-1, and 111-2 in FIGS. 16 and 17 can have a vertical dimension along a Z-axis (e.g., height) ranging from about 2 nm to about 50 nm. In some embodiments, a first ratio of the horizontal dimension to a width of S/D structures 110-1 and 110-2 can range from about 0.1 to about 0.8. In some embodiments, a second ratio of the vertical dimension to a height of S/D structures 110-1 and 110-2 can range from about 0.05 to about 0.8. Though FIGS. 9-17 illustrate one or two voids 111 in S/D structures 110, S/D structures 110 can have any number of voids 111.

Referring to FIG. 5, in operation 530, a gate structure is formed surrounding the stack of semiconductor layers. For example, as shown in FIGS. 1-4, gate structures 120 can replace sacrificial gate structures 620 and can be formed surrounding nanostructures 122. The replacement of sacrificial gate structures 620 can include removal of sacrificial gate structures 620, removal of nanostructures 621 to form n-type and p-type channel structures, and deposition of gate structures 120 surrounding nanostructures 122. In some embodiments, as shown in FIGS. 1-4, gate structures 120 can include gate dielectric layer 124 and gate electrode 112. In some embodiments, gate electrode 112 can include one or more work function metal layers and a metal fill. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

In some embodiments, the formation of gate structures 120 can be followed by the formation of S/D contact structures 130 as shown in FIGS. 1-4. In some embodiments, the formation of S/D contact structures 130 can be followed by the formation of interconnect structures, metal lines, metal vias, ILD layers, and other suitable processes to form semiconductor device 100 as shown in FIGS. 1-4. These processes are not described in detail for clarity.

Various embodiments in the present disclosure provide methods for forming a S/D structure with a void in a semiconductor device 100. In some embodiments, semiconductor device 100 can include a stack of nanostructures 122 on substrate 104. Gate structures 120 can wrap around nanostructures 122. S/D structures 110 can be formed on substrate 104 and in contact with nanostructures 122. S/D structures 110 can include one or more voids 111 below a top surface of S/D structures 110. In some embodiments, a first ratio of horizontal dimension 111w of void 111 to width 110w of S/D structures 110 can range from about 0.1 to about 0.8, and a second ratio of vertical dimension 111h of void 111 to height 110h of S/D structures 110 can range from about 0.05 to about 0.8. With voids 111 in S/D structures 110, the parasitic capacitance of S/D structures 110 can be reduced and the device performance of semiconductor device 100 can be increased.

In some embodiments, a semiconductor device includes a stack of semiconductor layers on a substrate, a gate structure surrounding the stack of semiconductor layers, and a source/drain (S/D) structure on the substrate and in contact with the stack of semiconductor layers. The S/D structure includes a void below a top surface of the S/D structure.

In some embodiments, a semiconductor device includes first and second stacks of semiconductor layers on a substrate, a first gate structure surrounding the first stack of semiconductor layers, a second gate structure surrounding the second stack of semiconductor layers, and a source/drain (S/D) structure between the first and second stacks of semiconductor layers. The S/D structure includes a void below a top surface of the S/D structure.

In some embodiments, a method includes forming a stack of semiconductor layers on a substrate, depositing a source/drain (S/D) structure on the substrate and in contact with the stack of semiconductor layers, and forming a gate structure surrounding the stack of semiconductor layers. The S/D structure includes a void below a top surface of the S/D structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a stack of semiconductor layers on a substrate;
a gate structure surrounding the stack of semiconductor layers; and
a source/drain (S/D) structure on the substrate and in contact with the stack of semiconductor layers, wherein the S/D structure comprises a void below a top surface of the S/D structure.

2. The semiconductor device of claim 1, wherein a ratio of a horizontal dimension of the void to a width of the S/D structure ranges from about 0.1 to about 0.8.

3. The semiconductor device of claim 1, wherein a ratio of a vertical dimension of the void to a height of the S/D structure ranges from about 0.05 to about 0.8.

4. The semiconductor device of claim 1, wherein the S/D structure comprises an additional void separated from the void.

5. The semiconductor device of claim 1, wherein the void is above a top surface of the substrate.

6. The semiconductor device of claim 1, further comprising an inner spacer between the S/D structure and the gate structure, wherein the void is partially enclosed by the inner spacer.

7. The semiconductor device of claim 1, further comprising a dielectric layer between the substrate and the S/D structure, wherein the void is above the dielectric layer and enclosed by the S/D structure.

8. The semiconductor device of claim 1, further comprising a dielectric layer between the substrate and the S/D structure, wherein the void is partially enclosed by the dielectric layer and the S/D structure.

9. The semiconductor device of claim 1, further comprising a dielectric layer on the S/D structure and an additional S/D structure on the dielectric layer, wherein the additional S/D structure comprises an additional void.

10. The semiconductor device of claim 1, further comprising a contact structure on the S/D structure, wherein a distance between the contact structure and the void ranges from about 4 nm to about 20 nm.

11. A semiconductor device, comprising:
first and second stacks of semiconductor layers on a substrate;
a first gate structure surrounding the first stack of semiconductor layers;
a second gate structure surrounding the second stack of semiconductor layers; and
a source/drain (S/D) structure between the first and second stacks of semiconductor layers, wherein the S/D structure comprises a void below a top surface of the S/D structure.

12. The semiconductor device of claim 11, wherein a first ratio of a horizontal dimension of the void to a width of the S/D structure ranges from about 0.1 to about 0.8 and a second ratio of a vertical dimension of the void to a height of the S/D structure ranges from about 0.05 to about 0.8.

13. The semiconductor device of claim 11, wherein the void is adjacent to the first stack of semiconductor layers and the S/D structure comprises an additional void adjacent to the second stack of semiconductor layers.

14. The semiconductor device of claim 11, further comprising:
a dielectric layer between the substrate and the S/D structure; and
an additional void in the S/D structure, wherein the void is adjacent to the dielectric layer and the additional void is above the void.

15. The semiconductor device of claim 11, further comprising:
a dielectric layer on the S/D structure; and
an additional S/D structure on the dielectric layer and comprising an additional void, wherein the dielectric layer and the additional S/D structure is between the first and second stacks of semiconductor layers.

16. A method, comprising:
forming a stack of semiconductor layers on a substrate;
depositing a source/drain (S/D) structure on the substrate and in contact with the stack of semiconductor layers, wherein the S/D structure comprises a void below a top surface of the S/D structure; and
forming a gate structure surrounding the stack of semiconductor layers.

17. The method of claim 16, wherein depositing the S/D structure comprises forming an additional void in the S/D structure separated from the void.

18. The method of claim 16, further comprising forming an inner spacer between the S/D structure and the gate structure, wherein the void is partially enclosed by the inner spacer.

19. The method of claim 16, further comprising forming a dielectric layer on the substrate prior to depositing the S/D structure, wherein the void is formed above the dielectric layer.

20. The method of claim 16, further comprising:
forming a dielectric layer on the S/D structure; and
forming an additional S/D structure on the dielectric layer, wherein the additional S/D structure comprises an additional void.
